(19) United States
(12) Patent Application Publication
(10) Pub. No.: US 2026/0206455 A1
(43) Pub. Date: Jul. 16, 2026

(54) LIGHT EMITTING DISPLAY DEVICE

(71) Applicant: LG Display Co., Ltd., Seoul (KR)

(72) Inventors: So Hee Lee, Paju-si (KR); Yong Cheol Kim, Paju-si (KR)

(21) Appl. No.: 19/373,967

(22) Filed: Oct. 30, 2025

(30) Foreign Application Priority Data
Nov. 12, 2024 (KR) 10-2024-0160312

(51) Int. Cl. H10K 59/00; H10K 59/35; H10K 101/30

(52) U.S. Cl. CPC H10K 59/771; H10K 59/353; H10K 2101/30

(57) ABSTRACT

A light emitting display device including a plurality of first electrodes each disposed at a respective subpixel among a plurality of subpixels on a substrate, a first common layer on the plurality of first electrodes, an electron blocking layer disposed on the first common layer and provided at a first subpixel among the plurality of subpixels, a first light emitting layer on the electron blocking layer, the first light emitting layer surrounding the electron blocking layer and having an edge that extends farther outward than an edge of the electron blocking layer, a second common layer on the first light emitting layer, and a second electrode on the second common layer.

### CROSS REFERENCE TO RELATED APPLICATIONS

Pursuant to 35 U.S.C. § 119(a), this application claims the benefit of an earlier filing date and right of priority to Korean Patent Application No. 10-2024-0160312, filed on Nov. 12, 2024, the contents of which are hereby incorporated by reference in their entirety for all purposes, as if fully set forth herein.

### TECHNICAL FIELD

The present disclosure generally relates to a display device.

### BACKGROUND

With the advent of the information society, there is increasing demand for various forms of display devices for displaying images.

A light emitting display device can include light emitting elements that constitute pixels, which can eliminate the need for a separate light source unit. This can be advantageous for slimness or flexibility and can provide excellent color purity.

### SUMMARY

In accordance with one aspect of the present disclosure, provided is a light emitting display device comprising a plurality of first electrodes each disposed at a respective subpixel among a plurality of subpixels on a substrate, a first common layer on the plurality of first electrodes, an electron blocking layer disposed on the first common layer and provided at a first subpixel among the plurality of subpixels, a first light emitting layer on the electron blocking layer, the first light emitting layer surrounding the electron blocking layer and having an edge that extends farther outward than an edge of the electron blocking layer, a second common layer on the first light emitting layer, and a second electrode on the second common layer.

In accordance with another aspect of the present disclosure, provided is a light emitting display device comprising a plurality of first electrodes each disposed at a respective one of a first subpixel, a second subpixel, and a third subpixel on a substrate, a first common layer on the plurality of first electrodes, the first common layer over the first, second, and third subpixels, a first electron blocking layer on the first common layer at the first subpixel, and a second electron blocking layer provided on the first common layer at the second and third subpixels, a green light emitting layer on the first electron blocking layer, and a red light emitting layer and a blue light emitting layer on the second electron blocking layer at the second and third subpixels, respectively, a second common layer on the green light emitting layer, the red light emitting layer, and the blue light emitting layer over the first to third subpixels and a second electrode on the second common layer.

It is to be understood that both the foregoing general description and the following detailed description of the disclosure are examples and explanatory and are intended to provide further explanation of the disclosure as claimed.

### BRIEF DESCRIPTION OF THE DRAWINGS

FIG. 1 is a schematic diagram illustrating an example of a light emitting display device according to one implementation of the present disclosure;

FIG. 2 is a plan view illustrating an example of a plurality of light emitting portions disposed in a part of an active area of FIG. 1;

FIG. 3 is a cross-sectional view along line I-I′ of FIG. 2;

FIG. 4 is a cross-sectional view illustrating an example of the configuration of an intermediate layer and a second electrode of a green subpixel in a light emitting display device according to an implementation of the present disclosure;

FIG. 5 is a cross-sectional view along line II-II′ of FIG. 2;

FIG. 6A is an example of an energy band diagram between a hole transport layer and a green light emitting layer in a PA region of FIG. 5;

FIG. 6B is an example of an energy band diagram between a hole transport layer and a green light emitting layer in a PB region of FIG. 5;

FIG. 7 is a cross-sectional view illustrating an example of the configuration of the intermediate layer and the second electrode of the green subpixel in a light emitting display device according to another implementation of the present disclosure;

FIG. 8 is an example of an energy band diagrams of red, green, and blue light emitting portions of the light emitting display device according to one implementation of the present disclosure; and

FIG. 9 is a graph showing an example of a change in luminance over time when the light emitting display devices of Comparative Example and Example are switched to the off state after driving.

### DETAILED DESCRIPTION

Implementations of the present disclosure can provide a light emitting display device that is capable of reducing or preventing poor image quality through smooth discharge when switched to an off state by changing the structure of a light emitting element.

A light emitting element can include two different electrodes and a light emitting layer between the electrodes. In order to increase luminous efficacy, as an example, the light emitting element can have various functional layers in addition to the luminous layer between the two electrodes, without being limited thereto.

A light emitting display device can display an image as subpixels repeatedly turn on and off. In order to display light of different colors, a color light emitting layer can be implemented to emit light of different colors, thereby functioning as a light emitting element. Different color light emitting layers can contain different materials. Accordingly, color light emitting layers of different colors from adjacent functional layers in different subpixels exhibit different interface characteristics. However, problems can occur when carrier accumulation occurs at the interface between a light emitting layer with a large energy band gap difference and an adjacent functional layer, and discharge may be delayed even after switching to an off state, thus resulting in defects.

Implementations of the present disclosure can provide a light emitting display device that is capable of preventing the phenomenon called “trailing shadow” in which luminance before an off state is delayed due to a discharge delay when switched to an off state.

Additional advantages, objects, and features of the disclosure will be set forth in part in the description which follows and in part will become apparent to those having ordinary skill in the art upon examination of the following, or may be learned from practice of the disclosure. The objectives and other advantages of the disclosure may be realized and attained by the structure particularly pointed out in the written description and claims hereof as well as the appended drawings.

Hereinafter, various implementations according to the present disclosure will be described in detail with reference to the attached drawings. Reference will now be made in detail to example implementations of the present disclosure, examples of which are illustrated in the accompanying drawings. Wherever possible, the same reference numbers will be used throughout the drawings to refer to the same or like parts, unless otherwise specified. Further, for convenience of description, a scale in which each of elements is illustrated in the accompanying drawings can differ from an actual scale. Thus, the illustrated elements are not limited to the specific scale in which they are illustrated in the drawings. The progression of processing steps and/or operations described is an example; however, the sequence of steps and/or operations is not limited to that set forth herein and may be changed as is known in the art, with the exception of steps and/or operations necessarily occurring in a particular order.

Advantages and features of the present disclosure, and a method of achieving the advantages and features will become apparent with reference to the example implementations described herein in detail together with the accompanying drawings. The present disclosure should not be construed as limited to the example implementations as disclosed below, and can be embodied in various different forms. Thus, these example implementations are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations maybe omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes (e.g., sizes, lengths, widths, heights, thicknesses, locations, radii, diameters, and areas), ratios, angles, numbers, and the like, which are illustrated in the drawings to describe various example implementations of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items. Any implementation described herein as an “example” is not necessarily to be construed as preferred or advantageous over other implementations. In construing an element, the element is construed as including an error range or tolerance range although there is no explicit description of such an error or tolerance range.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example implementations of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example implementations of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

In describing the various example implementations of the present disclosure, terms such as “first” and “second” “A,” “B,” “(a),” and “(b)” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various example implementations of the present disclosure can be partially or overall coupled to or combined with each other, and can be variously inter-operated with each other and driven technically as those skilled in the art can sufficiently understand. The implementations of the present disclosure can be carried out independently from each other, or can be carried out together in a co-dependent relationship.

Unless otherwise defined, all terms (including technical and scientific terms) used herein have the same meaning as commonly understood by one of ordinary skill in the art to which example implementations belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example implementations of the present disclosure will be described in detail with reference to the accompanying drawings. In adding reference numerals to elements of each of the drawings, although the same elements are illustrated in other drawings, like reference numerals can refer to like elements.

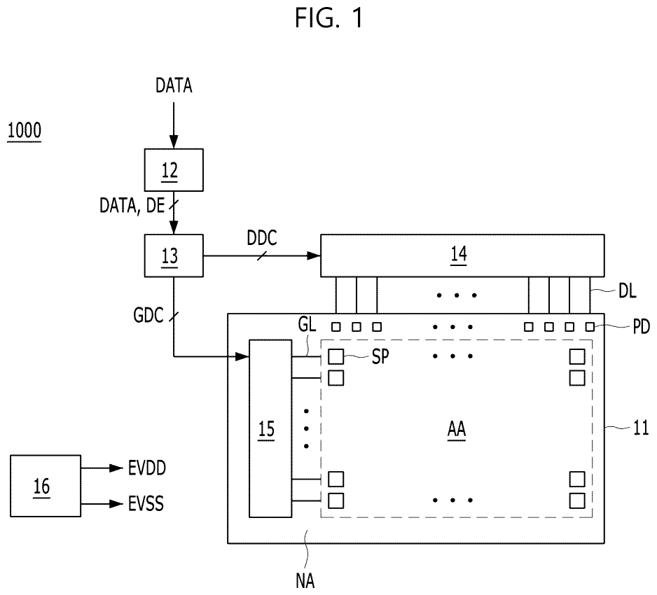

FIG. 1 is a schematic diagram illustrating an example of a light emitting display device according to one implementation of the present disclosure.

As shown in FIG. 1, the light emitting display device 1000 according to an implementation of the present disclosure includes a display panel 11, an image processor 12, a timing controller 13, a data driver 14, a scan driver 15, and a power supply 16. Implementations are not limited thereto. As an example, at least one or more of the above-mentioned components could be omitted, or at least one or more additional component may be further included.

The display panel 11 displays an image in response to a data signal (DATA) supplied from the data driver 14, a scan signal supplied from the scan driver 15, and power supplied from the power supply 16.

The display panel 11 may include subpixels SP disposed at each intersection of a plurality of gate lines GL and a plurality of data lines DL. The structure of the subpixel SP may vary depending on the type of the light emitting display device 1000.

For example, the subpixels SP may be formed in a top emission method, a bottom emission method, or a dual emission method depending on the structure. The subpixels SP are units that can emit light of their own color with or without a specific type of color filter. For example, the subpixels SP may include a red subpixel, a green subpixel, and a blue subpixel. Alternatively, the subpixel SP may include, for example, a red subpixel, a blue subpixel, a white subpixel, and a green subpixel. Implementations are not limited thereto. As an example, subpixels emitting light of a color such as cyan, magenta, or yellow, etc. other than red, blue, green and white may be additionally or alternatively included, without being limited thereto. The subpixels SP may have one or more different light emitting portions depending on the light emitting characteristics. For example, the blue subpixel and the subpixels emitting light with different color may have different light emitting portions, without being limited thereto.

One or more subpixels SP may constitute one unit pixel. For example, one unit pixel may include red, green, and blue subpixels, and the red, green, and blue subpixels may be repeatedly disposed. Alternatively, one unit pixel may include red, green, blue, and white subpixels, and the red, green, blue, and white subpixels may be disposed repeatedly, or the red, green, blue, and white subpixels may be disposed in quads. In an implementation according to the present disclosure, the color type, arrangement type, arrangement order, or the like of the subpixels may be determined depending on the light emission characteristics, lifespan of the device, device specifications, etc., and are not limited thereto.

The display panel 11 may be divided into an active area (AA: inside a dotted area) where subpixels SP are disposed to display an image, and a non-active area NA adjacent to the active area NA. As an example, the non-active area NA may be extended from the active area NA. As an example, the non-active area NA may fully or partially surround the active area NA, without being limited thereto. As an example, the non-active area NA may be at least partially or entirely invisible from a front side of the display panel 11, for example, by being bent toward a rear side of the display panel 11, without being limited thereto. As an example, the non-active area NA may be flat. As an example, the scan driver 15 may be mounted in the non-active area NA of the display panel 11, in the form of a gate in panel GIP method, or may be mounted on a separate panel or film, and then connected to the display panel 11 using a tape automated bonding (TAB) method, a chip-on-glass (COG) method, a chip-on-panel (COP) method, or a chip-on-film (COF) method, without being limited thereto. In addition, the non-active area NA may include a pad portion PAD including a pad electrode PD, without being limited thereto.

Here, the active area NA is also called a “display area” and the non-active area NA is also called a “non-display area”.

The image processor 12 may output a data enable signal DE in addition to a data signal DATA supplied from the outside. The image processor 12 may output one or more of a vertical synchronization signal, a horizontal synchronization signal, and a clock signal in addition to the data enable signal DE, but these signals are omitted for convenience of description.

The timing controller 13 may receive a data signal (DATA) in addition to a driving signal from the image processor 12. The driving signal may include a data enable signal DE. In addition, the driving signal may include a vertical synchronization signal, a horizontal synchronization signal, and a clock signal, without being limited thereto. The timing controller 13 includes a data timing control signal DDC for controlling the operation timing of the data driver 14 and a gate timing control signal GDC for controlling the operation timing of the scan driver 15 based on the driving signal.

The data driver 14 samples and latches the data signal DATA supplied from the timing controller 13 in response to the data timing control signal DDC supplied from the timing controller 13, converts the resulting data signal DATA into a gamma reference voltage, and outputs the gamma reference voltage.

The data driver 14 may output the data signal DATA through the data lines DL. The data driver 14 may be provided as an integrated circuit IC. For example, the data driver 14 may be electrically connected to the pad electrode PD disposed in the non-active area NA of the display panel 11 through a flexible circuit film (not shown), or may be mounted on the non-active area NA, without being limited thereto.

The scan driver 15 may output a scan signal in response to the gate timing control signal GDC supplied from the timing controller 13. The scan driver 15 may output a scan signal through the gate lines GL. The scan driver 15 may be implemented in the form of an integrated circuit IC or may be implemented in the display panel 11 in the form of a gate in panel GIP.

The power supply 16 may output a high potential voltage and a low potential voltage for driving the display panel 11. The power supply 16 may supply a high potential voltage to the display panel 11 through a first power line EVDD (driving power line or pixel power line) and supply a low potential voltage to the display panel 11 through a second power line (EVSS) (auxiliary power line or a common power line).

The display panel 11 is divided into an active area AA and a non-active area NA, and includes a plurality of subpixels SP defined by gate lines GL and data lines DL which cross each other in the active area AA to form a matrix.

The subpixels SP may include emitting subpixels that emit at least two light among red light, green light, blue light, yellow light, magenta light, and cyan light, without being limited thereto. In addition, the subpixels SP may emit their own color with or without a specific type of color filter, but the present disclosure is not necessarily limited thereto. The color, arrangement type, and arrangement order of the subpixels SP may be determined depending on light emission characteristics, lifespan of the device, and device specifications.

Each of the subpixels SP may include a light emitting portion that emits light and a non-light emitting portion around the light emitting portion.

Hereinafter, a light emitting display device that uses a light emitting element including a light emitting layer that emits a corresponding color to each of a red subpixel, a green subpixel, and a blue subpixel according to an implementation of the present disclosure will be described with reference to the drawings.

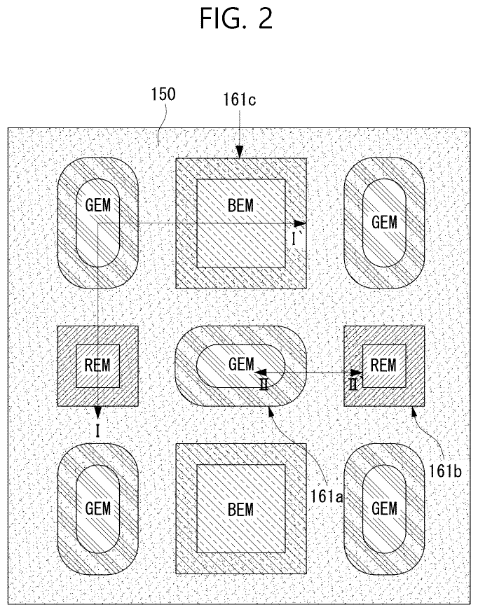

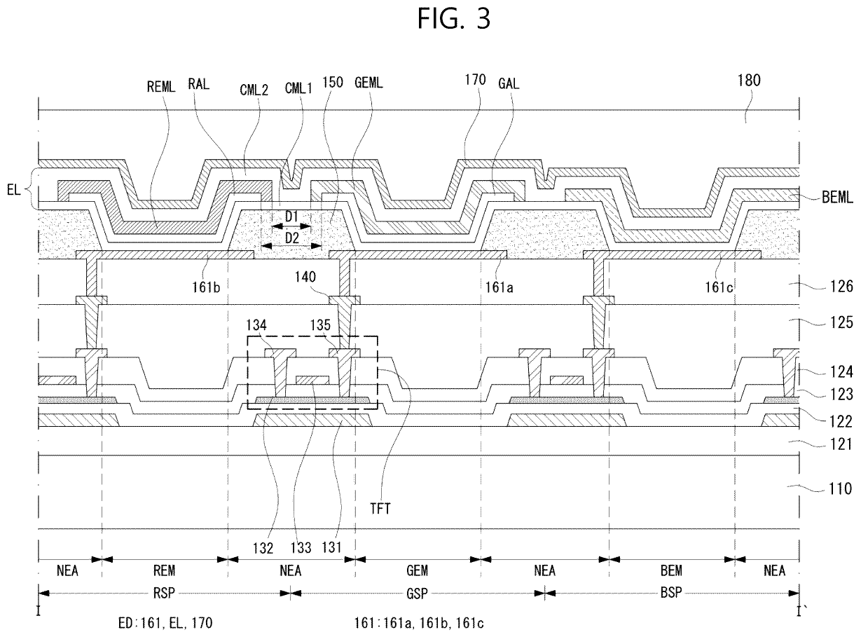

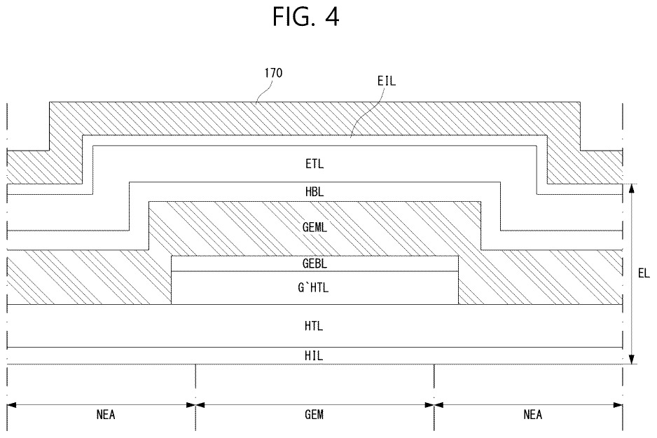

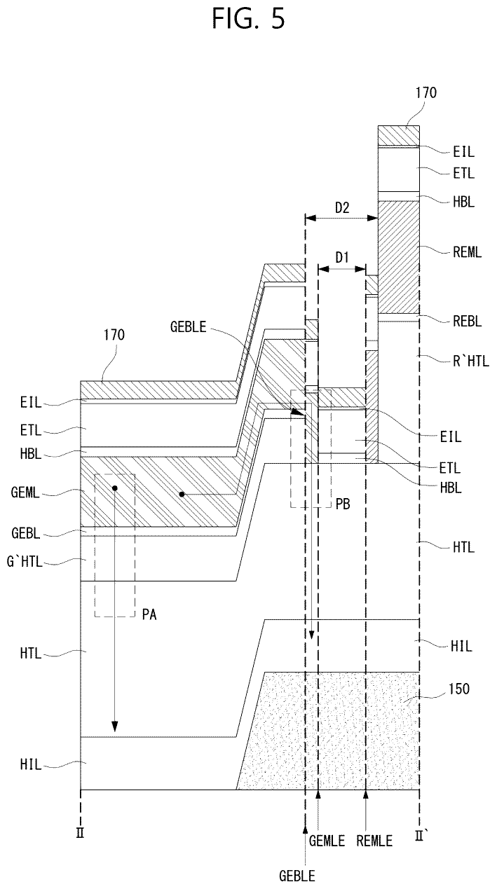

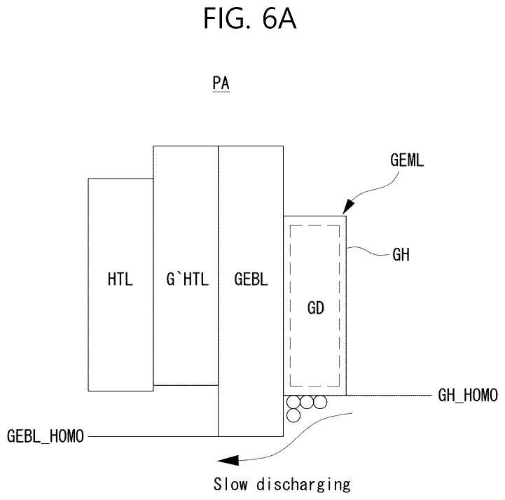

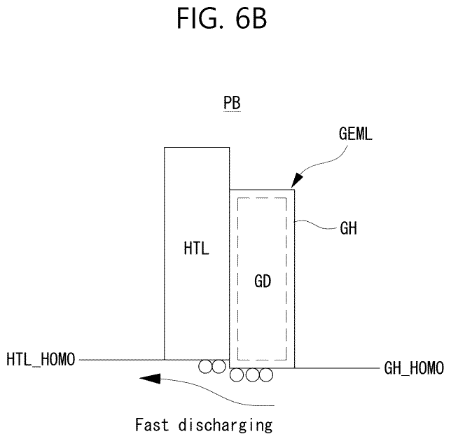

FIG. 2 is a plan view illustrating an example of a plurality of light emitting portions disposed in a part of an active area of FIG. 1. FIG. 3 is a cross-sectional view along line I-I′ of FIG. 2. FIG. 4 is a cross-sectional view illustrating an example of the configuration of an intermediate layer and a second electrode of a green subpixel in a light emitting display device according to an implementation of the present disclosure. FIG. 5 is a cross-sectional view along line II-II′ of FIG. 2. FIG. 6A is an example of an energy band diagram between a hole transport layer and a green light emitting layer in a PA region of FIG. 5. FIG. 6B is an example of an energy band diagram between a hole transport layer and a green light emitting layer in a PB region of FIG. 5.

As shown in FIGS. 2 and 3, the light emitting display device according to an implementation of the present disclosure includes regions of a plurality of subpixels RSP, GSP, BSP defined on a substrate 110 and light emitting elements ED emitting light of different colors provided at the plurality of subpixels RSP, GSP, BSP.

Each light emitting element ED includes a first electrode (161: 161a, 161b, 161c), an intermediate layer EL, and a second electrode 170. In addition, the intermediate layer EL may include a plurality of layers including light emitting layers REML, GEML, BEML.

The light emitting elements ED emitting light of different colors may have differences at least in the light emitting layers REML, GEML, BEML.

In addition, the intermediate layer EL includes a first common layer CML1 related to hole injection and transport between the first electrode (161: 161a, 161b, 161c) and the light emitting layer REML, GEML, BEML, and a second common layer CML2 related to electron transport and injection between the light emitting layer REML, GEML, BEML and the second electrode 170. Implementations are not limited thereto. As an example, at least one or both of the first common layer CML1 and the second common layer CML2 may be omitted depending on the design.

The first common layer CML1 may include layers commonly provided to the subpixels RSP, GSP, BSP, for example, a hole injection layer, a hole transport layer, or an electron blocking layer.

The second common layer CML2 may include layers commonly provided to the subpixels RSP, GSP, BSP, for example, a hole blocking layer, an electron transport layer, or an electron injection layer.

Each of the light emitting layers REML, GEML, BEML includes one or more hosts and one or more dopants. The red light emitting layer REML includes a red dopant, the green light emitting layer GEML includes a green dopant, and the blue light emitting layer BEML includes a blue dopant. The hosts of each light emitting layer REML, GEML, BEML transfer energy to the dopants included in each light emitting layer REML, GEML, BEML so that the dopants function to emit light. As an example, each dopant may include a phosphorescent and/or fluorescent dopant, without being limited thereto.

In the light emitting layer REML, GEML, BEML, when a voltage difference is applied between the first and second electrodes (161 (161a, 161b, 161c) and 170), holes are transferred through the first common layer CML1, electrons are transferred through the second common layer CML2, holes and electrons recombine with each other in the light emitting layer REML, GEML, BEML to form excitons, and the energy level of the excitons falls to the ground state, causing light emission.

When the subpixels RSP, GSP, BSP each emit red, green, and blue, the light emission peaks thereof are in the range of 605 nm to 650 nm, 505 nm to 590 nm, and 420 nm to 495 nm, respectively. The light emitting layers REML, GEML, BEML that emit light of different colors include different hosts and dopants at the respective subpixels RSP, GSP, BSP, and have different energy band gap characteristics and different mobilities.

The red, green, and blue subpixels RSP, GSP, BSP have different resonance conditions required to exhibit micro-cavity characteristics for different wavelengths. Therefore, the distances between the first electrode (161: 161a, 161b, 161c) and the second electrode 170 of the red, green, and blue subpixels RSP, GSP, BSP are different. The distance between the first electrode (161: 161a, 161b, 161c) and the second electrode 170 may be adjusted by controlling the thickness of the intermediate layer EL between the first and second electrodes 161 and 170, for example, by changing the thickness of the layer adjacent to the light emitting layer REML, GEML, BEML for each subpixel RSP, GSP, BSP.

FIG. 3 illustrates an example in which a red auxiliary layer RAL is provided under the red light emitting layer REML at the red subpixel RSP and a green auxiliary layer GAL is provided under the green light emitting layer GEML at the green subpixel GSP. And no auxiliary layer is provided under the blue light emitting layer BEML. As an example, the red auxiliary layer RAL and the green auxiliary layer GAL may be provided above the first common layer CML1, or may be provided under the first common layer CML1, without being limited thereto. However, implementations of the present disclosure are not limited thereto. At the blue subpixel BSP, a blue auxiliary layer may further be provided under the blue light emitting layer BEML. As an example, an auxiliary layer may be provided under any one or all of the red light emitting layer REML, the green light emitting layer GEML and the blue light emitting layer BEML, without being limited thereto. As an example, no auxiliary layer may be provided under any one of the red light emitting layer REML, the green light emitting layer GEML and the blue light emitting layer BEML, without being limited thereto.

As an example, the red auxiliary layer RAL, the green auxiliary layer GAL, and the blue auxiliary layer may include a hole transport material, without being limited thereto. As an example, the red auxiliary layer RAL may include a hole transport auxiliary layer R'HTL and/or an electron blocking layer REBL, without being limited thereto. The green auxiliary layer GAL may include a hole transport auxiliary layer G'HTL and an electron blocking layer GEBL, without being limited thereto. As an example, the first hole transport auxiliary layer G'HTL of the green auxiliary layer GAL and the second hole transport auxiliary layer R'HTL of the red auxiliary layer RAL may have different thicknesses, without being limited thereto. As an example, the optical distance nd (n is the average refractive index of the intermediate layer, d is the distance between the first and second electrodes) of each light emitting element is proportional to the wavelength. Therefore, when the green subpixel GSP and the red subpixel RSP satisfy the resonance condition in the same order, the red subpixel RSP corresponding to a longer wavelength may have a larger optical distance. Accordingly, the thickness of the second hole transport auxiliary layer R'HTL of the red subpixel RSP may be greater than the thickness of the first hole transport auxiliary layer G'HTL of the green subpixel GSP. Implementations are not limited thereto. As an example, at least one of the second hole transport auxiliary layer R'HTL, the first hole transport auxiliary layer G'HTL, the electron blocking layer REBL and the electron blocking layer GEBL may be omitted, or an additional auxiliary layer may be further provided under any one of the red light emitting layer REML and the green light emitting layer GEML, without being limited thereto. As an example, the green subpixel GSP and the red subpixel RSP may satisfy the resonance condition in different orders, without being limited thereto.

When the blue subpixel BSP satisfies the resonance condition in the same order as the red subpixel RSP and the green subpixel GSP, the blue subpixel BSP may not have a hole transport auxiliary layer, or may have a hole transport auxiliary layer having a thickness smaller than the thickness of the first and second hole transport auxiliary layers although it has a hole transport auxiliary layer, without being limited thereto.

Meanwhile, FIG. 3 illustrates an example of a structure in which the blue subpixel BSP does not have a blue auxiliary layer, but implementations of the present disclosure are not limited thereto. The blue subpixel BSP may also further include an electron blocking layer EBL under the blue light emitting layer BEML. As an example, the electron blocking layer EBL may be provided at each of the red, green, and blue subpixels RSP, GSP, BSP, or may be omitted at any one or more of the red, green, and blue subpixels RSP, GSP, BSP.

The electron blocking layer EBL is provided to reduce or prevent electrons from moving from the emitting layer toward the hole transport layer HTL. For this purpose, the electron blocking layer EBL contains a material having a higher LUMO level than the LUMO level of the light emitting layer. The electron blocking layer EBL contains a material having a LUMO level that is significantly different from the LUMO level of the light emitting layer so that it has a large barrier in the electron movement path at a position in contact with the light emitting layer. The electron blocking layer EBL contains a material having a larger energy band gap than the light emitting layer and functions to reduce or prevent electrons from escaping from the light emitting layer while ensuring stable hole transport.

Meanwhile, in one implementation of the present disclosure, as an example, the green auxiliary layer GAL and the red auxiliary layer RAL may be provided as a single layer and may function as a hole transport auxiliary layer to adjust the micro-cavity characteristics of each subpixel and an electron blocking layer to restrict electrons to the light emitting layer.

The light emitting display device according to one implementation of the present disclosure includes an intermediate layer EL structure in which a first common layer CML1, a green auxiliary layer GAL including a first hole transport auxiliary layer G'HTL, and an electron blocking layer GEBL, a green light emitting layer GEML, and a second common layer CML2 are sequentially stacked on a first electrode 161a at at least a green subpixel GSP, and further includes a second electrode 170 included on the second common layer CML2. In addition, the green light emitting layer GEML on the electron blocking layer GEBL is disposed to surround the electron blocking layer GEBL. The edge of the green light emitting layer GEML is disposed farther outward than the edge of the electron blocking layer GEBL, so that the green light emitting layer GEML surrounds the upper and side parts of the electron blocking layer GEBL. As an example, the green light emitting layer GEML on the electron blocking layer GEBL is disposed to surround the first hole transport auxiliary layer G'HTL, without being limited thereto. As an example, the edge of the green light emitting layer GEML is disposed farther outward than the edge of the first hole transport auxiliary layer G'HTL, so that the green light emitting layer GEML surrounds the side parts of the first hole transport auxiliary layer G'HTL, without being limited thereto.

Here, the green light emitting layer GEML is disposed to surround the edge of the electron blocking layer GEBL because the highest occupied molecular orbital (HOMO) energy level difference is large at the interface between the electron blocking layer GEBL and the green light emitting layer GEML, which are in direct contact within the green light emitting portion GEM. When switched from the off state to the on state, the light emitting element emits light, and when switched from the on state to the off state, the light emitting element is in a black state. When the light emitting element switches from the on state to the off state, carriers remaining in the light emitting layer are rapidly discharged toward the first electrode (anode) and the second electrode (cathode) on both sides, so that the light emitting element is in a normal black state. When the HOMO energy level difference between the light emitting layer and the adjacent functional layer, especially the electron blocking layer immediately adjacent to the light emitting layer, is large, holes are trapped and accumulated at the interface between the light emitting layer and the electron blocking layer, and weak light emission may be observed as a defect during discharge.

The HOMO energy level of the green light emitting layer in the structure of recently developed light emitting devices has a large difference from the HOMO energy level of the electron blocking layer due to the material, which causes a delay in charge discharge when switching from the on state to the off state in the green subpixel, and a phenomenon of trailing shadows in which the previous afterimage is observed for a predetermined period of time even after switching to the off state.

According to one implementation of the present disclosure, the light emitting display device has a configuration in which an edge of the green light emitting layer GEML is disposed farther outside an edge of the electron blocking layer GEBL at the green subpixel GSP, the green light emitting layer GEML surrounds upper and side parts of the electron blocking layer GEBL, and the green light emitting layer GEML directly contacts the first common layer CML1 outside the electron blocking layer GEBL.

The green light emitting layer GEML may include a green host GH and a green dopant GD. The HOMO energy level of the green light emitting layer GEML is dominantly affected by the green host GH included as a main component in the green light emitting layer GEML. The green host GH may be included singly or in combination. When a plurality of green hosts GH with different transport properties are included in the green light emitting layer GEML, the HOMO energy level of the green light emitting layer may be determined by the green host GH having a lower HOMO energy level. When the green light emitting layer GEML includes different green hosts GH, the hole mobility or electron mobility between the green hosts GH may be different.

The HOMO energy level GEBL_HOMO of the electron blocking layer GEBL is lower than the HOMO energy level GH_HOMO of the host of the green light emitting layer GEML, and as shown in FIG. 6A, the electron blocking layer GEBL with a large energy band gap may have a HOMO energy level much lower than the HOMO energy level of the green light emitting layer GEML.

As shown in FIG. 6B, the first common layer CML1 that contacts the green light emitting layer GEML on the outside of the electron blocking layer GEBL may be a hole transport layer HTL. The hole transport layer HTL has a smaller energy band gap and a higher HOMO energy level than the electron blocking layer GEBL.

As shown in FIGS. 6A and 6B, the second energy level gap GH-HOMO-HTL_HOMO between the HOMO energy levels of the host GH of the green light emitting layer GEML and the hole transport layer may be smaller than a first energy level gap GH_HOMO-GEBL_HOMO between the HOMO energy levels of the host GH of the green light emitting layer GEML and the electron blocking layer GEBL.

In the first region PA of the green light emitting portion GEM as shown in FIG. 5, the green light emitting layer GEML directly contacts the electron blocking layer GEBL and has a large HOMO energy level difference at the interface, so that partial slow discharge of charges occurs when switching to the off state as shown in FIG. 6A, but in the second region PB corresponding to the edge of the green light emitting layer GEML as shown in FIG. 5, the hole transport layer HTL with a small HOMO energy level difference directly contacts the green light emitting layer GEML, so that the holes remaining in the green light emitting layer GEML may be quickly discharged to the first electrode (anode) through the hole transport layer HTL, as shown in FIG. 6B. Accordingly, after switching to the off state, it is possible to realize a normal black state without defects such as trailing shadows due to the rapid discharge of charges.

The light emitting portions GEM, BEM, REM of the respective subpixels shown in FIG. 2 are examples of implementations of light emitting display devices and the light emitting display devices of implementations of the present disclosure are not limited thereto. Since human vision is highly sensitive to green wavelengths and the efficiency of green light emitting elements is high due to materials, the proportion of green subpixels is increased for luminance of display devices that display color light by disposing red, green, and blue subpixels. For example, FIG. 2 illustrates an example in which the number of green light emitting portions GEM is greater than the number of red light emitting portions REM and blue light emitting portions BEM. But implementations are not limited thereto. As an example, the number of green light emitting portions GEM may be the same as or smaller than the number of red light emitting portions REM and blue light emitting portions BEM, without being limited thereto. In FIG. 2, the green light emitting portions GEM are disposed in the shape of a horizontally long ellipse and a vertically long ellipse alternately in the diagonal direction. The red light emitting portions REM and the blue light emitting portions BEM are disposed alternately with the green light emitting portion GEM in the vertical or horizontal direction. The blue light emitting portion BEM may be disposed in a larger area than the light emitting portions of other colors in order to compensate for the low efficiency of the blue light emitting element. But implementations are not limited thereto. As an example, the shapes, sizes, arrangement of the green light emitting portions GEM, the red light emitting portions REM and the blue light emitting portions BEM may be changed in various ways. As an example, the green light emitting portions GEM, the red light emitting portions REM and the blue light emitting portions BEM may have the same shape or different shapes, and the same size or different sizes, without being limited thereto.

As an example, the first electrode 161a, 161b, 161c at each subpixel GSP, RSP, BSP may be provided with a larger area than the corresponding light emitting portion GEM, REM, BEM, without being limited thereto. Each edge of the first electrodes 161a, 161b, 161c overlaps the bank (150 in FIG. 3) and the area of the first electrode 161a, 161b, 161c exposed by the bank may function as the light emitting portion GEM, REM, BEM. The sizes of the light emitting portions GEM, REM, BEM may be uniform. The sizes of the light emitting portions GEM, REM, BEM may be different when the weights of the light emitting portions are different. FIG. 2 illustrates, as an example, a case where the blue light emitting portion BEM is larger than the light emitting portions of other colors, and more green light emitting portions GEM are disposed than the light emitting portions of other colors. In this arrangement, the weight of green may be increased to render white and the efficacy may be compensated when efficacy of blue is lower than that of other colors. However, this is merely provided as an example and implementations of the present disclosure are not limited thereto.

The first electrode (161: 161a, 161b, 161c) may function as an anode.

A green light emitting layer GEML, a red light emitting layer REML, and a blue light emitting layer BEML may be provided at each of the subpixels GSP, RSP, BSP with a size corresponding to that of the first electrode (161: 161a, 161b, 161c).

The stacked structure of the light emitting display device of the present disclosure will be described with reference to FIG. 3.

The substrate 110 on which each subpixel RSP, GSP, BSP is disposed may be formed of a single layer or multiple layers.

The substrate 110 may include at least one of a glass substrate, a plastic film, or a metal plate having a predetermined supporting force, without being limited thereto. The substrate 110 may be formed of a flexible material or a rigid material. For example, when the substrate 110 is formed as multiple layers, it may have a stacked structure of a first organic film, an inorganic insulating layer, and a second organic film, without being limited thereto. The first organic film on the outermost side may reduce or prevent the introduction of external impurities and have a protective function. The second organic film may function to planarize the formation surface of the internal array structure and to reduce or prevent charge transfer or impurity transfer from the outside to the inside. The inorganic insulating layer between the first and second organic films may function to reduce or prevent moisture diffusion between the first and second organic films, and transfer of conductive impurities to the second organic film.

A first insulating film 121 may be provided on the substrate 110. The first insulating film 121 may function as a buffer layer or an active buffer layer. The buffer layer and the active buffer layer may reduce or prevent transfer of impurities from the lower side of the wiring and active layer included in the internal array to the upper side and may support and protect the upper components. The first insulating film 121 may include multiple layers. As an example, the first insulating film 121 may be omitted depending on the design.

A thin film transistor TFT and a storage capacitor may be disposed on the first insulating film 121 at each subpixel RSP, GSP, BSP.

A light blocking layer 131 may be provided on the first insulating film 121 to reduce or prevent light from being transmitted from below to the active layer 132 of the thin film transistor TFT. As an example, the light blocking layer 131 may be omitted depending on the design. As an example, the light blocking layer 131 may be floated or connected with an electrode of the transistor TFT, without being limited thereto.

A second insulating film 122 may be disposed between the light blocking layer 131 and the active layer 132.

The thin film transistor TFT may be disposed on each of a plurality of subpixels on the second insulating film 122. For example, the thin film transistor TFT may include an active layer 132, a gate electrode 133 overlapping the active layer 132 with a third insulating film 123 interposed therebetween, and a first source-drain electrode 134 and a second source-drain electrode 135 connected to both sides of the active layer 132.

For example, a storage capacitor may include a first storage electrode and a second storage electrode overlapping each other. At least one of the first and second storage electrodes may be formed of the same material as the active layer 132 and the other may include the same material as the gate electrode 133, the first and second source-drain electrodes 134 and 135, or the light blocking layer 131, without being limited thereto.

The third insulating film 123 between the active layer 132 and the gate electrode 133 may function as a gate insulating film.

The active layer 132 may include, for example, a silicon-based semiconductor, an oxide semiconductor, a compound semiconductor, an organic semiconductor, etc. The silicon-based semiconductor may include crystalline and/or amorphous silicon. The oxide semiconductor may include at least one of gallium oxide, tin oxide, zinc oxide, indium oxide, iron oxide, or indium-gallium-zinc oxide, without being limited thereto. As an example, the oxide semiconductor layer may be formed of multiple layers having different materials or different material composition ratios, without being limited thereto. Each subpixel may include multiple thin film transistors and the thin film transistors may be disposed on different layers. For example, each subpixel of the substrate 110 may include multiple thin film transistors having different active layers or the same active layer, without being limited thereto. For example, the first thin film transistor may be formed as a silicon-based active layer and may be closer to the substrate 110, and the second thin film transistor may be formed as an oxide semiconductor active layer above the first thin film transistor.

The active layer 132 may include a channel region overlapping the gate electrode 133 and a source/drain region connected to each of the first and second source-drain electrodes 134 and 135.

The third insulating film 123 may be selectively disposed corresponding to the channel region of the active layer 132 or may be provided over the entire surface of the substrate 110 excluding the region through which the first and second source-drain electrodes 134 and 135 penetrate. The third insulating film 123 may function to insulate the active layer 132 from the gate electrode 133. The third insulating film 123 may be formed of an inorganic insulating material and may be formed as, for example, a silicon oxide film (SiOx), a silicon nitride film (SiNx), a silicon oxynitride film (SiOxNy), or a multilayer film thereof, without being limited thereto.

A gate electrode 133 may be formed on the third insulating film 123. The gate electrode 133 may be disposed to face the active layer 132 with the third insulating film 123 interposed therebetween.

A fourth insulating film 124 may be formed on the gate electrode 133 to cover and protect the gate electrode 133. In addition, the fourth insulating film 124 may function to protect at least one electrode, for example, the gate electrode 133 of the thin film transistor TFT and the active layer 132. The fourth insulating film 124 may be formed of an inorganic insulating material. For example, the fourth insulating film 124 may be formed as a silicon oxide film (SiOx), a silicon nitride film (SiNx), a silicon oxynitride film (SiOxNy), or a multilayer film thereof, without being limited thereto.

The first source-drain electrode 134 and the second source-drain electrode 135 may be disposed on the fourth insulating film 124. The fourth insulating film 124 and the third insulating film 123 may have contact holes to contact the first and second source-drain electrodes 134 and 135 at both ends of the active layer 132 and the corresponding areas may be removed.

The gate electrode 133 and the first and second source-drain electrodes 134 and 135 may each be formed as a single layer or multiple layers.

When the gate electrode 133 and the first and second source-drain electrodes 134 and 135 are single layers, they may be formed of one selected from the group consisting of molybdenum (Mo), aluminum (Al), chromium (Cr), gold (Au), titanium (Ti), nickel (Ni), neodymium (Nd), or copper (Cu), or an alloy thereof, without being limited thereto. In addition, when the gate electrode 133 and the first and second source-drain electrodes 134 and 135 include multiple layers, they may include double layers of molybdenum/aluminum-neodymium, molybdenum/aluminum, titanium/aluminum, or copper/molytitanium, without being limited thereto. Alternatively, the gate electrode 133 and the first and second source-drain electrodes 134 and 135 may include triple layers of molybdenum/aluminum-neodymium/molybdenum, molybdenum/aluminum/molybdenum, titanium/aluminum/titanium, or molybdenum/copper/molybdenum, without being limited thereto.

However, the configuration of the gate electrode 133 and the first and second source-drain electrodes 134 and 135 is not limited thereto, and the gate electrode 133 and the first and second source-drain electrodes 134 and 135 may include multiple layers formed of one selected from the group consisting of molybdenum (Mo), aluminum (Al), chromium (Cr), gold (Au), titanium (Ti), nickel (Ni), neodymium (Nd), or copper (Cu), or an alloy thereof, without being limited thereto.

The first to fourth insulating films 121, 122, 123, and 124 may each be formed as inorganic insulating films. The inorganic insulating film may be, for example, formed as at least one of a silicon oxide film, a silicon nitride film, or a silicon oxynitride film, without being limited thereto.

A fifth insulating film 125 and a sixth insulating film 126 may be formed on the first to fourth insulating films 121, 122, 123, 124. The fifth insulating film 125 may have a contact hole, and a connecting electrode 140 connected to the second source/drain electrode 135 may be formed within the contact hole. A sixth insulating film 126 is disposed to cover the connecting electrode 140 and the fifth insulating film 125. The fifth and sixth insulating films 125, 126 each include an organic material and may function as a planarizing film. The organic material may contain one or more of an acrylic resin, a phenolic resin, a polyimide resin, an unsaturated polyester resin, a polyamide resin, a benzocyclobutene, a polyphenylene resin, and a polyphenylene sulfide resin, without being limited thereto.

The connecting electrode 140 may be provided as multiple layers formed of one selected from the group consisting of molybdenum (Mo), aluminum (Al), chromium (Cr), gold (Au), titanium (Ti), nickel (Ni), neodymium (Nd), or copper (Cu), or an alloy thereof. However, implementations of the present disclosure are not limited thereto. In some cases, the connecting electrode 140 may be omitted. When the connecting electrode 140 is omitted, one of the first and second source-drain electrodes 134 and 135 may be directly connected to the first electrode (161: 161a, 161b, 161c) of the light emitting element ED. As an example, when the connecting electrode 140 is omitted, one of the fifth insulating film 125 and the sixth insulating film 126 may be omitted. Alternatively, as an example, one or more additional insulating film may be further included.

The light emitting element ED is formed by stacking a first electrode (161: 161a, 161b, 161c), an intermediate layer EL, and a second electrode 170. The first electrode (161: 161a, 161b, 161c) is independently provided at each subpixel GSP, RSP, BSP as shown in FIGS. 2 and 3, and is separated from adjacent subpixels. At least the first and second common layers (CML1, CML2) and the second electrode 170 of the intermediate layer EL may be commonly provided at the subpixels GSP, RSP, BSP. The first electrode (161: 161a, 161b, 161c) is independently provided at each subpixel GSP, RSP, BSP, so that the light emitting elements EDs of the subpixels GSP, RSP, BSP may be driven independently.

The first electrode (161: 161a, 161b, 161c) may pass through the sixth insulating film 126 and the fifth insulating film 125 and be connected to the transistor TFT. FIG. 3 illustrates an example in which a connecting electrode 140 is further provided between the first electrode (161: 161a, 161b, 161c) and the transistor TFT, and an example in which the transistor TFT is connected to the connecting electrode 140, and the connecting electrode 140 is connected to the first electrode (161: 161a, 161b, 161c). However, implementation of the present disclosure is not limited thereto, and the second source/drain electrode 135 of the transistor TFT and the first electrode (161: 161a, 161b, 161c) of the light emitting element ED may be directly connected without the connecting electrode.

The first electrode (161: 161a, 161b, 161c) may include, for example, a conductive material, such as a metal material. As an example, the first electrode (161: 161a, 161b, 161c) may include a metal material having high reflectivity or a transparent electrode, without being limited thereto. For example, the first electrode (161: 161a, 161b, 161c) is formed with a single layer structure of a transparent conductive film such as ITO (indium tin oxide), IZO (indium zinc oxide), TO (tin oxide), ITZO (indium tin zinc oxide), an APC (Ag/Pd/Cu) alloy, or a multilayered structure such as a stacked structure (Ti/Al/Ti) of aluminum (Al) and titanium (Ti), a stacked structure (ITO/Al/ITO) of aluminum (Al) and ITO, a stacked structure (ITO/APC/ITO) of an APC alloy and ITO, a stacked structure (Ag/MoTi) of silver (Ag) and molybdenum/titanium alloy, or a single layer structure formed of one material selected from silver (Ag), aluminum (Al), molybdenum (Mo), gold (Au), magnesium (Mg), calcium (Ca), or barium (Ba), or an alloy thereof, without being limited thereto. The first electrode may include a single-layer structure formed of a material. When the first electrode (161: 161a, 161b, 161c) is formed of a single layer of a transparent conductive film, light from the light emitting element ED may pass through the first electrode (161: 161a, 161b, 161c) and be emitted. When the first electrode (161: 161a, 161b, 161c) includes a reflective electrode, light may be emitted through the second electrode 170 facing the first electrode (161: 161a, 161b, 161c).

In the light emitting display device of the top emission type, the second electrode 170 may include a transparent electrode or a thin reflective-transparent electrode that allows light transmission through the second electrode 170 to be possible. The transparent electrode may include, for example, ITO, IZO, or the like, and the reflective-transparent electrode may be formed of, for example, one material selected from silver (Ag), aluminum (Al), molybdenum (Mo), gold (Au), magnesium (Mg), ytterbium (Yb), strontium (Sr), or an alloy thereof, without being limited thereto.

Alternatively, in the bottom-emission type light emitting display device, the second electrode 170 may include a reflective electrode. For example, the reflective electrode may include one material selected from silver (Ag), aluminum (Al), molybdenum (Mo), gold (Au), magnesium (Mg), calcium (Ca), or barium (Ba), or an alloy thereof, but is not limited to the examples. The second electrode 170 may be a light-transmitting electrode. The second electrode 170 may include a transparent metal material (TCO, transparent conductive material) such as ITO (indium tin oxide) or IZO (indium zinc oxide) that can transmit light, or a semi-transmissive metal material such as magnesium (Mg), silver (Ag), or an alloy of magnesium (Mg) and silver (Ag). When the second electrode 170 includes a semi-transmissive metal material, the light emission efficiency may be increased by a microcavity. When the second electrode 170 includes a semi-transmissive metal material, the thickness thereof may be small enough to transmit light.

An intermediate layer EL is provided on the first electrode (161: 161a, 161b, 161c). The intermediate layer EL may include a first common layer CML1 related to holes of a hole injection layer HIL and a hole transport layer HTL, a light emitting layer EML, a hole blocking layer HBL, and a second common layer CML2 related to electrons of an electron transport layer ETL and an electron injection layer EIL.

FIGS. 4 and 5 illustrate an example in which the intermediate layer EL at a green subpixel GSP includes a hole injection layer HIL, a hole transport layer HTL, a first hole transport auxiliary layer G'HTL, an electron blocking layer GEBL, a green light emitting layer GEML, a hole blocking layer HBL, an electron transport layer ETL, and an electron injection layer EIL. Here, the green light emitting layer GEML is provided in the upper and side parts of the electron blocking layer GEBL so as to surround an edge GEBLE of the electron blocking layer GEBL. Accordingly, the edge GEMLE of the green light emitting layer GEML is farther outside than the edge GEBLE of the electron blocking layer. Through this configuration, the lower-most surface of the green light emitting layer GEML contacts the hole transport layer HTL having a small HOMO energy level difference, so that holes do not remain in the green light emitting layer GEML in the off state, but may be smoothly emitted to the first electrode 161a through the hole transport layer HTL in contact therewith. Accordingly, when switching from the on state to the off state, carriers are quickly emitted to the first electrode 161a, thereby reducing or preventing defects such as trailing shadow in the off state and obtaining black without light leakage. As an example, the green light emitting layer GEML may be continues at the edge GEBLE of the electron blocking layer GEBL. As an example, the green light emitting layer GEML may have a greater thickness than the overall thickness of the electron blocking layer GEBL and the first hole transport auxiliary layer G'HTL, so that the green light emitting layer GEML disposed on the electron blocking layer GEBL and the green light emitting layer GEML disposed on the hole transport layer HTL may be connected to each other.

Here, the edge GEMLE of the green light emitting layer GEML and the edge GEBLE of the electron blocking layer GEBL overlap the upper surface of the bank 150 corresponding to the non-light emitting portion. This aims at reducing or preventing loss of the light emitting area in the green light emitting portion GEM when the green subpixel GSP is driven.

Meanwhile, the hole injection layer HIL and the hole transport layer HTL are layers related to hole injection and transport and are continuously provided without interruption at the subpixels GSP, RSP, BSP. Therefore, the hole injection layer HIL and the hole transport layer HTL are also continuously provided in the red subpixel RSP adjacent to the green subpixel GSP.

The first hole transport auxiliary layer G'HTL is a layer that adjusts the optical distance depending on the resonance condition of the green subpixel GSP, and is spaced apart from the second hole transport auxiliary layer R'HTL that is adjusted depending on the resonance condition of the red subpixel RSP, as shown in FIGS. 3 and 5.

The implementations illustrated in FIGS. 4 and 5 show an example in which the first hole transport auxiliary layer G'HTL is provided to have the same edge as the electron transport layer GEBL that is patterned inside the green light emitting layer GEML. In this case, the first hole transport auxiliary layer G'HTL and the electron transport layer GEBL of the green subpixel GSP may be patterned using the same mask, so that the electron blocking layer EBL may be patterned without an additional mask, which has advantages of optimizing the process and improving the yield. But implementations are not limited thereto. As an example, the first hole transport auxiliary layer G'HTL may be provided to have an edge different from that of the electron transport layer GEBL. As an example, the first hole transport auxiliary layer G'HTL may have a greater size or smaller size than the electron transport layer GEBL, without being limited thereto. As an example, the first hole transport auxiliary layer G'HTL may surround the edge of the electron transport layer GEBL, without being limited thereto.

FIG. 4 illustrates an example of a stack of an intermediate layer EL and a second electrode 170 based on a green light emitting portion GEM and FIG. 5 illustrates a non-light emitting portion on the side of an adjacent red subpixel RSP along with the green light emitting portion GEM.

Referring to FIGS. 3 and 5, the red light emitting layer REML is also provided to surround the edge of the patterned electron blocking layer REBL in the red subpixel RSP. Implementations are not limited thereto. As an example, the red light emitting layer REML may not be provided to surround the edge of the patterned electron blocking layer REBL in the red subpixel RSP. As an example, the blue light emitting layer BEML may be or may not be provided to surround the edge of the patterned electron blocking layer in the blue subpixel BSP.

The red light emitting layer REML of the red subpixel RSP may be spaced apart from the green light emitting layer GEML by at least a first distance D1 to reduce or prevent color mixing between adjacent subpixels GSP, RSP.

The light emitting display device according to one implementation of the present disclosure of FIG. 5 illustrates an example in which the electron blocking layer GEBL of the green subpixel GSP is patterned along with the electron blocking layer REBL of the red subpixel RSP. As an example, the edge REMLE of the red light emitting layer REML is disposed outside the edge of the electron blocking layer REBL. In this case, the electron blocking layers GEBL, REBL at the green subpixel GSP and the red subpixel RSP are provided independently from each other and spaced apart from each other by a second distance D2. In this case, the electron blocking layers GEBL, REBL provided at the subpixels may be formed using a single electron blocking layer formation process. As an example, by preparing a deposition mask for forming an electron blocking layer including an opening having a narrower width than an opening of a deposition mask for forming the light emitting layer GEML, REML, the electron blocking layer may be formed at each subpixel GSP, RSP through a single electron blocking layer formation process. Similarly, the electron blocking layer EBL may also be formed in the blue subpixel BSP.

In this case, the light emitting display device of implementations of the present disclosure has an electron blocking layer GEBL, REBL that is independently distinguished in each subpixel. The electron blocking layer GEBL, REBL having a patterned structure may be formed independently and may each be formed through a single formation process using the same material. Therefore, the electron blocking layer GEBL, REBL has a patterned structure without adding a process or material and thus the light emitting display device may easily emit carriers in the off state. Implementations are not limited thereto. As an example, the electron blocking layer GEBL, REBL having a patterned structure may be formed independently and may each be formed through separate formation processes using the same or different materials, without being limited thereto.

Meanwhile, in another implementation of the light emitting display device of the present disclosure, the patterned structure of the electron blocking layer GEBL may be only for the green subpixel GSP. In this case, as an example, the electron blocking layer EBL in the red subpixel RSP may be connected to the electron blocking layer EBL in the blue subpixel BSP, without being limited thereto.

The implementation described above illustrates an example in which the first hole transport auxiliary layer G'HTL and the electron blocking layer GEBL for the green subpixel GSP are formed using the same deposition mask in order to reduce the number of deposition masks, and the second hole transport auxiliary layer R'HTL and the electron blocking layer REBL for the red subpixel RS may have the same width, without being limited thereto.

Meanwhile, an encapsulation layer 180 configured to protect the light emitting element ED may be further provided on the second electrode 170. The encapsulation layer 180 may be a single layer or multiple layers. When the encapsulation layer 180 is formed as multiple layers, it may be formed by stacking at least one inorganic encapsulation film and at least one organic encapsulation film, without being limited thereto. The inorganic encapsulation film may reduce or prevent moisture penetration and the organic encapsulation film may cover particles and flatten the surface. On a plane, as an example, the organic encapsulation film may be disposed inside the inorganic encapsulation film, without being limited thereto. In this case, the inorganic encapsulation film may reduce or prevent penetration of moisture to the side part.

As an example, a touch sensor and/or a protective film having a touch sensing function may be further provided on the encapsulation layer 180, without being limited thereto.

Another implementation of the present disclosure will be described below.

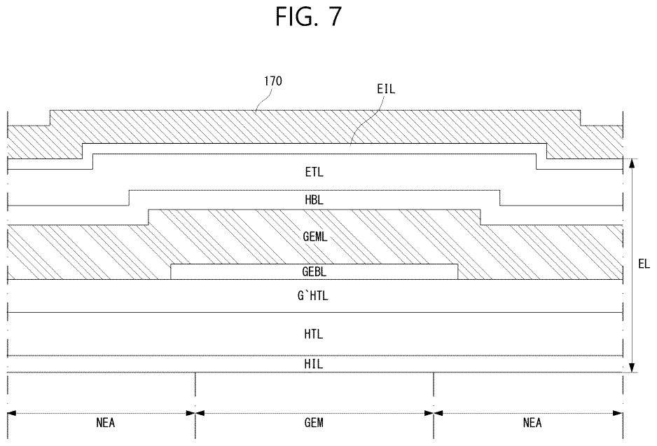

FIG. 7 is a cross-sectional view illustrating an example of the configuration of the intermediate layer and the second electrode of the green subpixel in a light emitting display device according to another implementation of the present disclosure.

As shown in FIG. 7, the same effect may be achieved although the green light emitting layer GEML of the green subpixel GSP may surround the edge of the electron blocking layer GEBL and the lower surface of the green light emitting layer GEML directly contacts the first hole transport auxiliary layer G'HTL.

Since the first hole transport auxiliary layer G'HTL also has a smaller HOMO energy level difference from the green light emitting layer GEML than from the electron blocking layer EBL, when the green subpixel is switched to the off state, holes are easily released through the first hole transport auxiliary layer G'HTL, the hole transport layer HTL, and the hole injection layer HIL through the green light emitting layer GEML disposed outside the electron blocking layer GEBL using the structure of FIG. 7. As an example, the green light emitting layer GEML may have a thickness greater than that of the electron blocking layer GEBL, so that the green light emitting layer GEML may be continues at an edge of the electron blocking layer GEBL, without being limited thereto.

Meanwhile, the light emitting display device according to the implementation of FIG. 7 may be formed without an additional mask using the same mask for depositing the first hole transport auxiliary layer G'HTL and the green light emitting layer GEML.

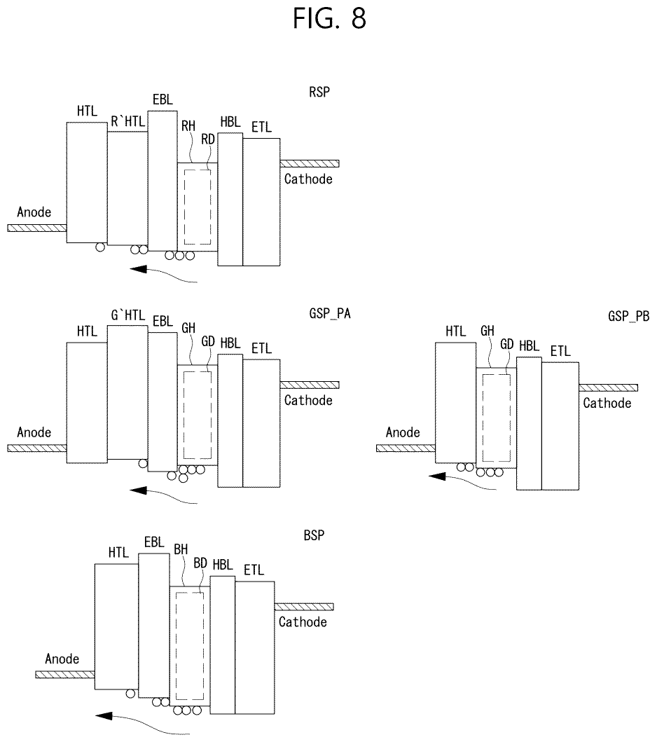

FIG. 8 is an example of an energy band diagram of red, green, and blue light emitting portions of the light emitting display device according to an implementation of the present disclosure.

FIG. 8 illustrates an example of a light emitting display device of the present disclosure and shows release of carriers including holes when a red subpixel RSP, a green subpixel GSP, and a blue subpixel BSP in the light emitting display device include a hole transport layer HTL, an electron blocking layer EBL, a hole blocking layer HBL, and an electron transport layer ETL formed of the same material between the first electrode (anode) and the second electrode (cathode).

The hole injection layer and the electron injection layer are not shown in the drawings because they are much thinner than the hole transport layer HTL or the electron transport layer ETL and do not act as a barrier against carrier transfer due to almost no trapping tendency thereof.

For the micro-cavity characteristics, the green subpixel GSP compared to the blue subpixel BSP further includes a first hole transport auxiliary layer G'HTL between the hole transport layer HTL and the green light emitting layer GH+GD, and the red subpixel RSP further includes a second hole transport auxiliary layer R'HTL between the hole transport layer HTL and the red light emitting layer RH+RD.

With respect to the light emitting portion GSP_PA of the green subpixel, the electron blocking layer EBL having a lower HOMO energy level than the HOMO energy level of the green light emitting layer GH+GD acts as a barrier when the carriers such as holes move to the electron blocking layer EBL when switched to the off state. However, the green light emitting layer GEML contacts the hole transport layer HTL having a higher HOMO energy level at the non-light emitting region PB outside the green light emitting portion GEM in the extended green subpixel GSP so as to facilitate release of holes. The holes bypass this area and are thus rapidly released from the actual green light emitting layer GEML, so that the green subpixel GSP becomes a black state without leakage without any defects such as trailing shadow when the green subpixel is off. Meanwhile, the HOMO energy level of the hole transport layer HTL has a difference of less than 0.4 eV from the HOMO energy level of the green host GH in the green light emitting layer, which takes into account not only the rapid emission of holes when switched to the off state, but also the rapid transfer of holes from the first electrode (anode) to the green light emitting layer GEML when driven.

Compared to the green subpixel GSP, the electron blocking layer EBL of the red subpixel RSP has a HOMO energy level almost identical to the red host RH of the red light emitting layer, and the electron blocking layer EBL of the blue subpixel BSP has a HOMO energy level higher than the blue host (BH) of the blue light emitting layer, which means that holes are easily emitted when switched to the off state.

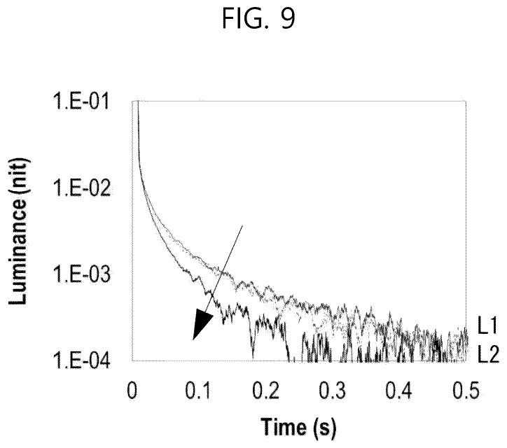

FIG. 9 is a graph showing an example of a change in luminance over time when the light emitting display devices of Comparative Example and Comparative are switched to an off state after driving.

In FIG. 9, L1 represents luminance over time after switching to the off state of Comparative Example in which the electron blocking layer is continuously provided in all subpixels, and L2 represents luminance over time after switching to the off state of Example in which the edge of the light emitting layer extends farther outward than the edge of the electron blocking layer such that the light emitting layer surrounds the edge of the electron blocking layer according to one implementation of the present disclosure.

As shown in FIG. 9, in Comparative Example L1, light leakage occurs for more than 0.5 seconds after switching to the off state, but in Example L 2 according to one implementation of the present disclosure, almost no light leakage occurs after 0.2 seconds. As an example, in a specific subpixel, even if the electron blocking layer and the light emitting layer, which have a large HOMO energy level difference, have a configuration in which they are in contact in the region of the light emitting portion, and even if the light emitting layer has an interface in which it directly contacts the electron blocking layer, the edge of the light emitting layer surrounds the electron blocking layer and the edge of the light emitting layer directly contacts the hole transport layer disposed thereunder, so that carriers such as holes are easily released from the light emitting layer through the hole transport layer having a small HOMO energy level difference.

Therefore, the light emitting display device according to one implementation of the present disclosure may be in a normal black state without defects such as trailing shadow by rapid discharge of charges after switching to the off state.

The implementations of the present disclosure may be applied to a light emitting display device in which light emitting layers of different colors are applied to respective subpixels.

Hereinabove, the example has been described in which a green light emitting layer of a green subpixel surrounds a patterned electron blocking layer on the lower side and has an edge farther outside the edge of the electron blocking layer, but implementations of the present disclosure are not limited thereto. In other color subpixels, an edge may be provided farther outside the edge of the electron blocking layer on the lower side to provide the effect of discharging charges accumulated in the light emitting element when switched to an off state.

The green subpixel expresses relatively white luminance among the red, green, and blue subpixels, and has a large proportion. Therefore, in a light emitting display device, the edge of the green light emitting layer in at least the green subpixel may be designed to protrude further than the edge of the electron blocking layer on the lower side, so that the green light emitting layer combines with a hole transport layer or a hole transport auxiliary layer further below the electron blocking layer on the outer side than the edge of the electron blocking layer, thereby further improving the discharge effect in the off state.

In addition, the light emitting display device according to one implementation of the present disclosure may be applied in an example in which at least one of the light emitting elements of the subpixels has a tandem structure of multiple stacks. For example, the tandem structure of multiple stacks may include a plurality of stacks each disposed between first and second electrodes with a charge generation layer therebetween, and each stack may include a first hole-transporting common layer, a light emitting layer, and a second electron-transporting common layer. The charge generation layer may have a stack structure of, for example, an n-type charge generation layer and a p-type charge generation layer. Accordingly, the n-type charge generation layer may be in contact with the first common layer of the adjacent lower stack and the p-type charge generation layer may be in contact with the second common layer of the adjacent upper stack.

The light emitting display devices of implementations of the present disclosure have the following effects.

Even if the light emitting layer has an interface where it directly contacts the electron blocking layer in the region of the light emitting portion where the HOMO energy level difference is large, the edge of the light emitting layer surrounds around the electron blocking layer and the edge of the light emitting layer directly contacts the hole transport layer on the lower side, so that carriers such as holes are easily released from the light emitting layer through the hole transport layer having a small HOMO energy level difference.

Therefore, it is possible to achieve a normal black state without defects such as trailing shadows by rapid discharge of charges after switching to the off state.

A light emitting display device according to one implementation of the present disclosure may comprise a first electrode at each of a plurality of subpixels on a substrate, a first common layer on the first electrode, an electron blocking layer on the first common layer, the electron blocking layer at a first subpixel among the plurality of subpixels, a first light emitting layer on the electron blocking layer, the first light emitting layer surrounding the electron blocking layer and having an edge that extends farther outward than an edge of the electron blocking layer, a second common layer on the first light emitting layer and a second electrode on the second common layer.

In a light emitting display device according to one implementation of the present disclosure, a lower-most surface of the first light emitting layer disposed farther outward the edge of the electron blocking layer may be in contact with the first common layer.

In a light emitting display device according to one implementation of the present disclosure, a HOMO energy level of the electron blocking layer may be lower than a HOMO energy level of a host of the first light emitting layer. A first energy level gap between HOMO energy levels of the electron blocking layer and the host of the first light emitting layer may be larger than a second energy level gap between HOMO energy levels of the host of the first light emitting layer and the first common layer.

A light emitting display device according to one implementation of the present disclosure may further comprise a first hole transport auxiliary layer between the first common layer and the electron blocking layer at the first subpixel.

In a light emitting display device according to one implementation of the present disclosure, an edge of the first hole transport auxiliary layer may be disposed at a same area as an edge of the first light emitting layer. Or an edge of the first hole transport auxiliary layer may be disposed farther inward than the edge of the first light emitting layer.

In a light emitting display device according to one implementation of the present disclosure, the edge of the first hole transport auxiliary layer may be disposed at a same area as the edge of the electron blocking layer or is disposed farther outward than the edge of the electron blocking layer.

In a light emitting display device according to one implementation of the present disclosure, the lower-most surface of the first light emitting layer disposed farther outward than the edge of the electron blocking layer may be in contact with the first hole transport auxiliary layer.

In a light emitting display device according to one implementation of the present disclosure, a HOMO energy level of the electron blocking layer may be lower than a HOMO energy level of a host of the first light emitting layer. A first energy level gap between HOMO energy levels of the electron blocking layer and the host of the first light emitting layer may be larger than a third energy level gap between HOMO energy levels of the host of the first light emitting layer and the first hole transport auxiliary layer.

In a light emitting display device according to one implementation of the present disclosure, the first light emitting layer may have an emission peak at a wavelength of 510 nm to 590 nm.

A light emitting display device according to one implementation of the present disclosure may further comprise a second light emitting layer having an emission peak at a wavelength of 600 nm to 650 nm or a third light emitting layer having an emission peak at a wavelength of 420 nm to 490 nm between the first common layer and the second common layer at a second subpixel adjacent to the first subpixel.

A light emitting display device according to one implementation of the present disclosure may further comprise a second hole transport auxiliary layer and an adjacent electron blocking layer between the first common layer and the second light emitting layer.

Each of the second hole transport auxiliary layer and the adjacent electron blocking layer may be spaced apart from the first light emitting layer.

In a light emitting display device according to one implementation of the present disclosure, a thickness of the second hole transport auxiliary layer may be greater than a thickness of the first hole transport auxiliary layer.

A light emitting display device according to one implementation of the present disclosure may further comprise a stack of the adjacent electron blocking layer and the second light emitting layer to emit light of different colors from the first light emitting layer between the first common layer and the second common layer at the second subpixel adjacent to the first subpixel.

In a light emitting display device according to one implementation of the present disclosure, a HOMO energy level difference between the second light emitting layer and the adjacent electron blocking layer may be smaller than a HOMO energy level difference between the first light emitting layer and the electron blocking layer.

A light emitting display device according to one implementation of the present disclosure may further comprise a bank to open light emitting portions of the plurality of subpixels. An edge of the first light emitting layer and an edge of the second light emitting layer may overlap top surfaces of the bank at different positions.

In a light emitting display device according to one implementation of the present disclosure, the electron blocking layer and the adjacent electron blocking layer may comprise the same material.

A light emitting display device according to one implementation of the present disclosure may comprise a first electrode at each of a first subpixel, a second subpixel, and a third subpixel on a substrate, a first common layer on the first electrode, the first common layer over the first to third subpixels, a first electron blocking layer on the first common layer at the first subpixel, and a second electron blocking layer provided on the first common layer at the second and third subpixels, a green light emitting layer on the first electron blocking layer, and a red light emitting layer and a blue light emitting layer on the second electron blocking layer at the second and third subpixels, respectively, a second common layer on the green light emitting layer, the red light emitting layer, and the blue light emitting layer over the first to third subpixels and a second electrode on the second common layer.

The green light emitting layer may surround the first electron blocking layer and have an edge disposed farther outward than an edge of the first electron blocking layer.

In a light emitting display device according to one implementation of the present disclosure, a lower-most surface of the green light emitting layer disposed farther outside an edge of the first electron blocking layer may be in contact with the first common layer.

In a light emitting display device according to one implementation of the present disclosure, a HOMO energy level of the first electron blocking layer may be lower than a HOMO energy level of a host of the green light emitting layer. A first energy level gap between HOMO energy levels of the first electron blocking layer and the host of the green light emitting layer may be larger than a second energy level gap between HOMO energy levels of the host of the green light emitting layer and the first common layer.

In a light emitting display device according to one implementation of the present disclosure, the red light emitting layer, the blue light emitting layer, and the second electron blocking layer are spaced apart from the green light emitting layer, respectively.

It will be apparent to those skilled in the art that various modifications and variations may be made in the disclosure without departing from the spirit or scope of the disclosure. Thus, it is intended that the disclosure cover such modifications and variations thereof, provided they fall within the scope of the appended claims and their equivalents.

What is claimed is:

1. A light emitting display device comprising:
a plurality of first electrodes each disposed at a respective subpixel among a plurality of subpixels on a substrate;
a first common layer on the plurality of first electrodes;
an electron blocking layer on the first common layer, the electron blocking layer at a first subpixel among the plurality of subpixels;
a first light emitting layer on the electron blocking layer, the first light emitting layer surrounding the electron blocking layer and having an edge that extends farther outward than an edge of the electron blocking layer;
a second common layer on the first light emitting layer; and
a second electrode on the second common layer.

2. The light emitting display device according to claim 1, wherein a lower-most surface of the first light emitting layer is disposed farther outward than the edge of the electron blocking layer and is in contact with the first common layer in a region around the electron blocking layer.

3. The light emitting display device according to claim 1, wherein a highest occupied molecular orbital (HOMO) energy level of the electron blocking layer is lower than a HOMO energy level of a host of the first light emitting layer, and
a first energy level gap between the HOMO energy level of the electron blocking layer and the HOMO energy level of the host of the first light emitting layer is larger than a second energy level gap between the HOMO energy level of the host of the first light emitting layer and a HOMO energy level of the first common layer.

4. The light emitting display device according to claim 1, further comprising a first hole transport auxiliary layer between the first common layer and the electron blocking layer at the first subpixel.

5. The light emitting display device according to claim 4, wherein an edge of the first hole transport auxiliary layer is disposed at a same area as the edge of the first light emitting layer or is disposed farther inward than the edge of the first light emitting layer.

6. The light emitting display device according to claim 5, wherein the edge of the first hole transport auxiliary layer is disposed at a same area as the edge of the electron blocking layer or is disposed farther outward than the edge of the electron blocking layer.

7. The light emitting display device according to claim 4, wherein the lower-most surface of the first light emitting layer disposed farther outward than the edge of the electron blocking layer is in contact with the first hole transport auxiliary layer in a region around the electron blocking layer.

8. The light emitting display device according to claim 7, wherein a HOMO energy level of the electron blocking layer is lower than a HOMO energy level of a host of the first light emitting layer, and
a first energy level gap between the HOMO energy level of the electron blocking layer and the HOMO energy level of the host of the first light emitting layer is larger than a third energy level gap between the HOMO energy level of the host of the first light emitting layer and a HOMO level of the first hole transport auxiliary layer.

9. The light emitting display device according to claim 1, wherein the first light emitting layer has an emission peak at a wavelength of 510 nm to 590 nm.

10. The light emitting display device according to claim 9, further comprising a second light emitting layer having an emission peak at a wavelength of 600 nm to 650 nm or a third light emitting layer having an emission peak at a wavelength of 420 nm to 490 nm between the first common layer and the second common layer at a second subpixel adjacent to the first subpixel.

11. The light emitting display device according to claim 10, further comprising a second hole transport auxiliary layer and an adjacent electron blocking layer between the first common layer and the second light emitting layer,
wherein each of the second hole transport auxiliary layer and the adjacent electron blocking layer are spaced apart from the first light emitting layer.

12. The light emitting display device according to claim 11, wherein a thickness of the second hole transport auxiliary layer is greater than a thickness of the first hole transport auxiliary layer.

13. The light emitting display device according to claim 11, further comprising a stack of the adjacent electron blocking layer and the second light emitting layer to emit light of different colors from the first light emitting layer between the first common layer and the second common layer at the second subpixel adjacent to the first subpixel.

14. The light emitting display device according to claim 13, wherein a HOMO energy level difference between the second light emitting layer and the adjacent electron blocking layer is smaller than a HOMO energy level difference between the first light emitting layer and the electron blocking layer.

15. The light emitting display device according to claim 13, further comprising a bank configured to expose light emitting portions of the plurality of subpixels,
wherein the edge of the first light emitting layer and an edge of the second light emitting layer overlap a top surface of the bank at different positions.

16. The light emitting display device according to claim 13, wherein the electron blocking layer and the adjacent electron blocking layer comprise the same material.

17. A light emitting display device comprising:
a plurality of first electrodes each disposed at a respective one of a first subpixel, a second subpixel, and a third subpixel on a substrate;
a first common layer on the plurality of first electrodes, the first common layer over the first, second, and third subpixels;
a first electron blocking layer on the first common layer at the first subpixel, and a second electron blocking layer provided on the first common layer at the second subpixel and the third subpixel;
a green light emitting layer on the first electron blocking layer, and a red light emitting layer and a blue light emitting layer on the second electron blocking layer at the second subpixel and the third subpixel, respectively;
a second common layer on the green light emitting layer, the red light emitting layer, and the blue light emitting layer over the first, second, and third subpixels; and
a second electrode on the second common layer,
wherein the green light emitting layer surrounds the first electron blocking layer and has an edge that extends farther outward than an edge of the first electron blocking layer.

18. The light emitting display device according to claim 17, wherein a lower-most surface of the green light emitting layer is disposed farther outside than the edge of the first electron blocking layer and is in contact with the first common layer in a region around the first electron block layer.

19. The light emitting display device according to claim 17, wherein a highest occupied molecular orbital (HOMO) energy level of the first electron blocking layer is lower than a HOMO energy level of a host of the green light emitting layer, and
a first energy level gap between the HOMO energy level of the first electron blocking layer and the HOMO energy level of the host of the green light emitting layer is larger than a second energy level gap between the HOMO energy level of the host of the green light emitting layer and a HOMO energy level of the first common layer.

20. The light emitting display device according to claim 17, wherein the red light emitting layer, the blue light emitting layer, and the second electron blocking layer are each spaced apart from the green light emitting layer.
